(19) United States
(12) Patent Application Publication
(10) Pub. No.: US 2007/0064477 A1
(43) Pub. Date: Mar. 22, 2007

(54) System for remote data sharing

(75) Inventors: Kevin E. Dorow, Kennewick, WA (US); Steven V. Shoemaker, Burbank, WA (US); Michael W. White, Richland, WA (US)

Correspondence Address: BATTELLE MEMORIAL INSTITUTE;ATTN: IP SERVICES, K1-53, P. O. BOX 999, RICHLAND, WA, 99352, US

(73) Assignee: Battelle Memorial Institute, Richland, WA (US)

(21) Appl. No.: 11/231,727

(22) Filed: Sep. 20, 2005

(51) Int. Cl. G11C 16/04

(52) U.S. Cl. 365/185.01

(57) ABSTRACT

Embodiments of the present invention encompass a remote data sharing system that can support connectivity between any JDBC-compliant data source and any Java-compatible remote client, which system can be implemented without programming. The system can comprise at least one JDBC-compliant data source, a gateway running inside a Java-compliant web container, and a plurality of remote clients. The system allows for platform-independent data sharing.

### STATEMENT REGARDING FEDERALLY SPONSORED RESEARCH OR DEVELOPMENT

This invention was made with Government support under Contract DE-AC0576RLO1830 awarded by the U.S. Department of Energy. The Government has certain rights in the invention.

### BACKGROUND

Traditional remote data sharing frameworks are typically designed to function with specific data sources and/or remote clients. Thus, connectivity is often limited to specific types of data sources and remote client platforms. Furthermore, access to data can traditionally require the use of development toolkits, thereby calling for ad-hoc programming solutions. Therefore, a need exists for a remote data sharing system that can support connectivity between any JDBC-compliant data source and any Java-compatible remote client, which system can be implemented without programming.

### SUMMARY

An embodiment of the present invention encompasses a system for remote data sharing that automatically adapts to access any Java Database Connectivity (JDBC) data source. The system comprises at least one data source, a gateway running inside a Java-compliant web container, and a plurality of remote clients. The data sources should comply with JDBC technology. Examples of data sources can include, but are not limited to databases, flat files, spreadsheets, and combinations thereof. The gateway manages the data sources and routes at least one data view between the data sources and the remote clients, wherein the data views comprise data and presentation metadata. The remote clients each comprise a data-sharing application, which application automatically adapts the data views to all remote-client platforms that comply with Java or (HTML) standards. The data-sharing application also processes the data views and dynamically generates a user interface according to the presentation metadata. Accordingly, information from data sources can be shared with remote clients without requiring users to provide software programming, for example, by utilizing software development kits (SDK).

Examples of remote clients can include, but are not limited to, Blackberry® devices, PocketPC® devices, PalmOne® devices, personal digital asssistants, cellular phones, digital music players, gaming devices, and combinations thereof.

The system can support bidirectional communication, wherein the remote clients can add or alter data to or from the data source, respectively. In such an instance, the data-sharing application can format the data that is to be sent back to the data source.

In one embodiment, the gateway can provide an interface for creating data mappings. The interface can be implemented using Java servlets. Accordingly, the gateway can comprise an internal data store to hold data mapping definitions.

In another embodiment, the system can further comprise a graphical data presentation application on the remote clients. The graphical data presentation application can read the data, the mapping definitions, and the presentation metadata to generate a display to the user. It can also provide appropriate controls for adding and/or altering data.

In yet another embodiment, the system can support secure communications, which can comprise secure socket layers (SSL) and/or user authentication.

### DESCRIPTION OF DRAWINGS

Embodiments of the invention are described below with reference to the following accompanying drawings.

FIG. 1 is a schematic representation of an embodiment of the system architecture.

FIG. 2 is a screenshot that serves as an example of an interface for naming and creating mapping data.

FIG. 3 is a screenshot that serves as an example of a display generated by the graphical data presentation application.

FIG. 4 is a flowchart of an embodiment of the system's operation.

### DETAILED DESCRIPTION

Embodiments of the present invention are based on Java technology and can provide a universal system for sharing data between remote clients and any JDBC-compliant data source. The remote clients can be any device on which a Java virtual machine exists and can provide a platform-independent user interface to the data of interest. In one embodiment, data views are self-describing. As used herein, self-describing can refers to a self-describing format that contains both content and metadata, which metadata describes both presentation and editing rules for the content. In one embodiment, the format uses American Standard Code for Information Interchange (ASCII).

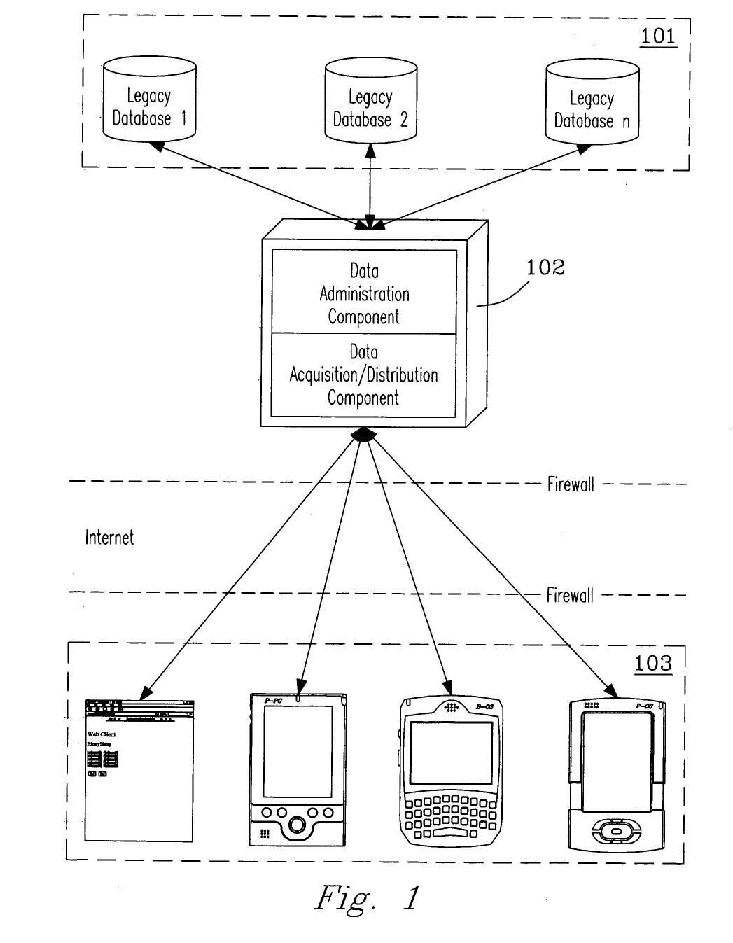

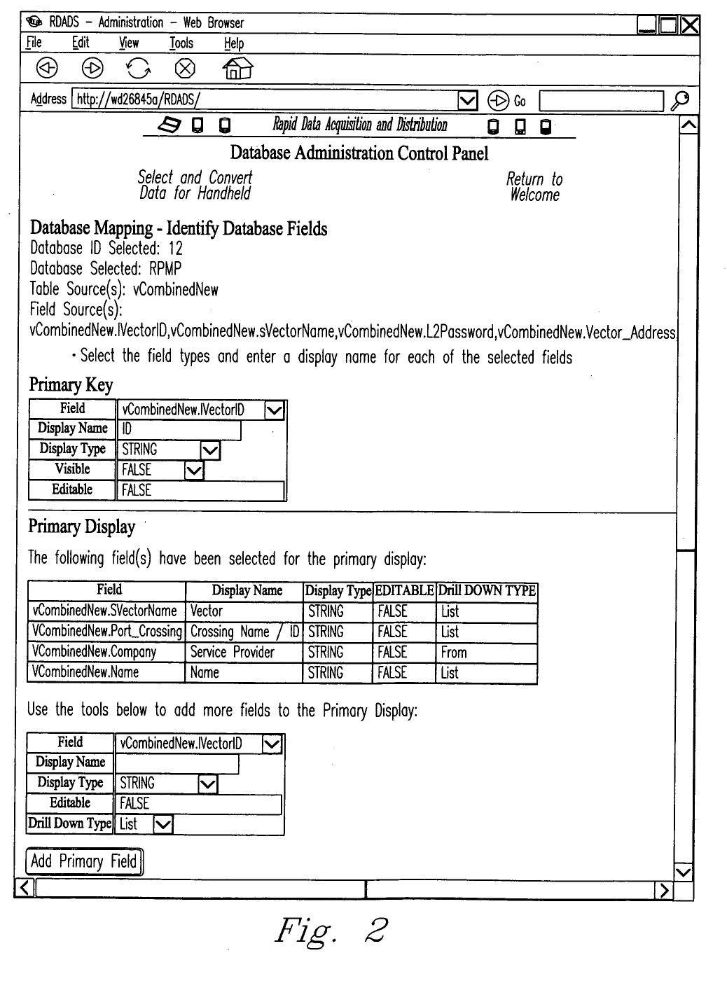

Referring to the embodiment shown in FIG. 1, examples of JDBC-compliant data sources 101 can include, but are not limited to databases such as Microsoft SQL server, Oracle, MySQL, and flat file databases. The gateway 102 can comprise a web server and can host a data administration application that provides an interface to define and manage connections to the data sources. The data administration application can utilize JDBC reflection to connect and/or interrogate the data sources. It can also provide an interface allowing an administrator and/or user to define information to be shared. Java servlets can be used to generate the interface for naming and creating mapping data, wherein the mapping data can define the information to be shared and how it is shared. FIG. 2 shows a screenshot, which serves as an example of such an interface.

The gateway 102 can further comprise a data distribution/acquisition application that can accept and process requests for data mappings and receive updated information from the remote clients 103. For example, the data distribution/acquisition application can comprise Java servlets that accept post requests from remote clients. As used herein, a post can refer to new mapping data to be transferred. A post can also refer to data that has been modified by a remote client along with the name of the associated mapping data. When information is being requested by the remote client, the appropriate data mapping definition, which can comprise data source connection information and an SQL query statement, is utilized to retrieve the information to be shared directly from the data source. Additionally, the content of the data view can be formatted to ASCII text. When modified information is being sent by the remote client, the appropriate SQL and connection information is utilized, as defined in the mapping data, and the modified information is stored on the data source. Both the data distribution/acquisition and the data administration applications can be web-based.

Examples of remote clients 103 can include, but are not limited to, Palm devices, Pocket PC devices, Blackberry devices, computers having web browsers, portable entertainment devices, portable mp3 players, and cellular phones. Each remote client can comprise a data sharing application. The data sharing application can comprise two sub-applications, a data conduit and a graphical data presentation application. Furthermore, the data can be searched and/or sorted according to algorithms known in the art.

The data conduit can acquire data views from the gateway and adapt the data view to the appropriate device-dependent format. Data requests can occur via hyper-text transfer protocol (HTTP). Similarly, modified data from the remote client can be converted to a format that allows transmission to the data source via HTTP.

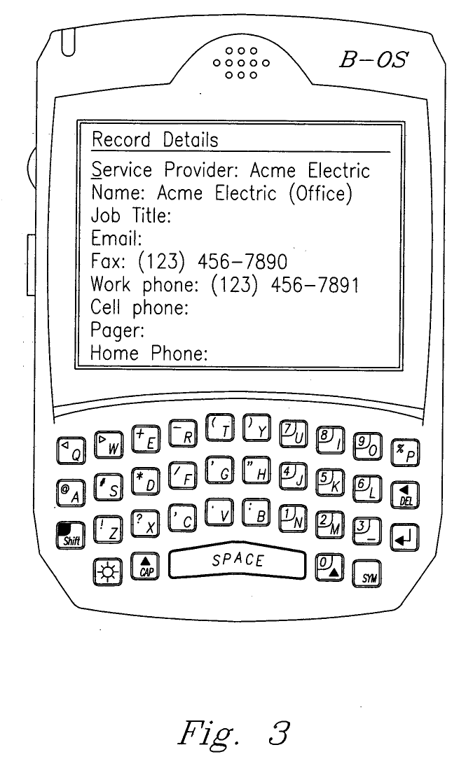

The graphical data presentation application can read the data view and generate a display according to the presentation metadata contained therein. Furthermore, the graphical data presentation application can generate displays of the controls for adding and/or updating data to be uploaded on the data source. Generation of the interface can be dynamic. The interface can be a drill-down list having forms at any level of the list. Field types can include, but are not limited to strings, numbers, date, time, and images. FIG. 3 shows a screenshot that serves as an example of a display generated by the graphical data presentation application.

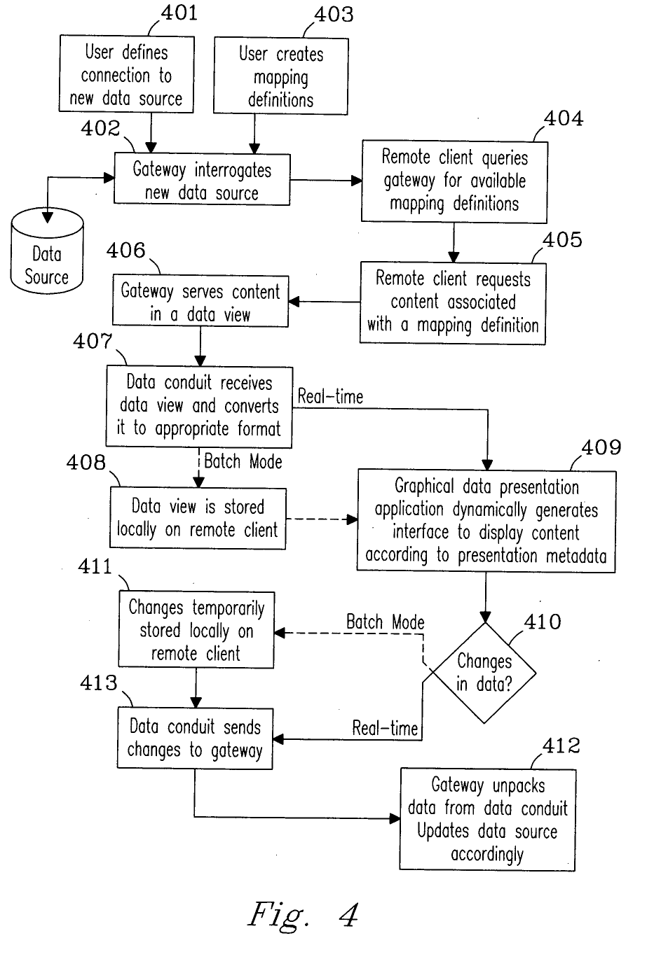

An example of the system's operation is represented schematically by a flowchart in FIG. 4. If a data source has not already been defined, an administrative user can define a connection to a new data source 401. The gateway interrogates the new data source and extracts metadata 402, which can comprise tables, fields, and relationships. In one embodiment, the gateway can include data storage means in which the extracted metadata can be locally stored. Examples of data storage means can include, but are not limited to disk-based devices, random access memory, and flash memory.

The administrative user can create mapping definitions 403, which can define the content and visual representation of the data to be shared with the remote clients. The remote clients, via the data sharing application, can query the gateway for a listing of the available content according to the mapping definitions 404. If a remote client requests specific content 405 according to one of the available mapping definitions, the gateway can serve the content in a data view 406. In serving the data, the gateway can extract the data from the data source, or the local storage means, package the data, and send it to the remote client via HTTP and/or HTTPS. Packaging of the data can include creating a data view that contains the data (i.e., content) and presentation metadata that describes how the data will be displayed and what the editing rules are.

When operating in real-time mode, the gateway can provide the desired content as it is requested. The data view can be converted into a format appropriate for the particular remote client platform 407. When operating in batch mode, the converted data view can be stored locally on the remote client 408. Real-time operation can occur for devices maintaining a communication link with the gateway. For devices that need to be synced and/or experience poor wired and/or wireless reception, the system can utilize batch-mode operation.

Using the graphical presentation application, the remote client can generate an interface 409 to display the content according to the presentation metadata contained in the data views. The graphical presentation application can also generate displays having controls to manipulate and/or alter the data. If changes in the data occur 410, a remote client operating in real-time mode can send the changes to the gateway using the data conduit 413. In batch mode, the changes can be temporarily stored locally on the remote client 411. At the next sync or instance of acceptable wired/wireless connection, the changes can be sent to the gateway 413. Transmission of from the data conduit to the gateway can occur via HTTP and/or HTTPS. The gateway unpacks the data from the data conduit and updates the data source accordingly 412.

While a number of embodiments of the present invention have been shown and described, it will be apparent to those skilled in the art that many changes and modifications may be made without departing from the invention in its broader aspects. The appended claims, therefore, are intended to cover all such changes and modifications as they fall within the true spirit and scope of the invention.

We claim:

1. A system for remote data sharing comprising:
a. at least one data source, wherein the data sources are JDBC-compliant;
b. a gateway running inside a Java-compliant web container, wherein the gateway manages the data sources and routes at least one data view between the data sources and remote clients, said data views comprising data and presentation metadata; and
c. a plurality of remote clients each comprising a data-sharing application,. wherein the data-sharing application automatically adapts data views to all remote-client platforms complying with Java or HTML standards, processes the data views, and dynamically generates a user interface according to the presentation metadata;
wherein the system automatically adapts to access any of the JDBC-compliant data sources.

2. The system as recited in claim 1, wherein the data-sharing application validates and formats data to be sent back to data source.

3. The system as recited in claim 1, supporting secure communications.

4. The system as recited in claim 3, wherein the secure communications comprises secure socket layers (SSL).

5. The system as recited in claim 1, supporting user authentication.

6. The system as recited in claim 1, wherein the data sources are selected from the group consisting of databases, flat files, spreadsheets, and combinations thereof.

7. The system as recited in claim 1, wherein the gateway further comprises an internal data store

8. The system as recited in claim 1, wherein the remote client comprises a device selected from the group consisting of a Blackberry®, PocketPC®, personal digital assistant, cellular phone, digital music player, gaming device, computer having a web browser, and combinations thereof.

9. The system as recited in claim 1, further comprising a graphical data presentation application.

10. The system as recited in claim 1, wherein said routing of data views occurs in real-time or batch-mode.
